(19) United States
(12) Patent Application Publication
(10) Pub. No.: US 2017/0323843 A1
(43) Pub. Date: Nov. 9, 2017

(54) Gas-Cooled 3D IC with Wireless Interconnects

(71) Applicants: Amlan Ganguly, Rochester, NY (US); Satish G. Kandlikar, Rochester, NY (US)

(72) Inventors: Amlan Ganguly, Rochester, NY (US); Satish G. Kandlikar, Rochester, NY (US)

(73) Assignee: Rochester Institute of Technology, Rochester, NY (US)

(21) Appl. No.: 15/587,634

(22) Filed: May 5, 2017

Related U.S. Application Data
(60) Provisional application No. 62/332,135, filed on May 5, 2016.

(51) Int. Cl. H01L 23/467; H01L 25/065; H01L 23/522; H01L 27/06

(52) U.S. Cl. CPC H01L 23/467; H01L 27/0688; H01L 25/0657; H01L 23/5226; H01L 2225/06531; H01L 2225/06589

(57) ABSTRACT

A three-dimensional integrated circuit includes two or more stacks of one or more active layers; a gas-cooling layer separating the two or more stacks and a wireless interconnect between the two or more stacks enabling communication between the two or more stacks and system including a gas-cooled three-dimensional integrated circuit having wireless data interconnects is disclosed.

### CROSS REFERENCE

This application claims the benefit of the filing date of U.S. Provisional Patent Application Ser. No. 62/332,135, filed May 5, 2016, which is hereby incorporated by reference in its entirety.

This invention was made with government support under grant number CCF-1162123 awarded by U.S. National Science Foundation. The government has certain rights in this invention.

### FIELD

The present disclosure relates to a gas-cooled three dimensional integrated circuit having wireless interconnects.

### BACKGROUND

Three-dimensional Integrated Circuits (3D ICs) have emerged as a feasible solution to overcome the performance limitation of 2D planar ICs (Topol et al. 2010). However, utilizing the third dimension to provide additional device layers poses thermal challenges as stacking vertical layers significantly increases the power dissipation density and the thermal footprint per unit area (Mizunuma et al. 2011). Convectional cooling techniques are limited in ability to extract heat only from the top or bottom of the entire 3D stack. In some cases, edges are also used for cooling. Design of sophisticated cooling mechanisms are required to alleviate the thermal issues in 3D ICs.

One such solution is where embedded inter-layer cooling microchannels or a cooling chip is inserted in between layers of the 3-D chip. Tuckerman and Pease (Tuckerman et al. 1981) first proposed the use of microchannels to effectively cool IC chips. Microchannels between the active layers of the 3D ICs circulating cooled liquids can extract the heat from the interlayer regions thus more effectively cooling the 3D ICs compared to conventional cooling techniques. However, through silicon vias (TSVs) that are mainly used as vertical interconnect technology to enable data transfers across different device layers, are not suitable to be used across the cooling layer. This is because from a thermal viewpoint, the microchannels are desired to be tall, while longer TSV's will increase data transmission delays (Kandlikar et al. 2014). In addition, taller TSVs cannot be reliably manufactured due to high aspect ratios. Widening TSVs to lower the aspect ratios results in reduced floor area severely restricting place and route options for the interconnects. Narrower channels also cause significant pressure variations in the liquid cooling channels compromising the structural integrity of a 3D IC and the TSV based interconnects. The manufacturing process also becomes significantly complex as the TSVs and liquid microchannels will co-exist between the layers. The co-design of TSVs and microfluidic cooling channels is very challenging (Dang et al. 2010). On-Chip wireless interconnects operating in the 60 GHz millimeter-wave (mm-wave) have been shown to improve energy efficiency and bandwidth of traditional planar NoC architectures (Deb et al. 2010). The art currently lacks integration of such wireless interconnects in 3D NoCs for data communication across the microchannels in the hope of alleviating the height restrictions imposed by the cooling layers while providing energy efficient data communication.

### SUMMARY

In accordance with one aspect of the present disclosure, there is provided a three-dimensional integrated circuit, including two or more vertical stacks of one or more active layers; a gas-cooling layer separating the two or more stacks and a wireless interconnect between the two or more stacks enabling communication between the two or more vertical stacks.

In accordance with another aspect of the present disclosure, there is provided a system including a gas-cooled three-dimensional integrated circuit comprising internal wireless data interconnects; a gas source in fluid communication with the gas-cooled three-dimensional integrated circuit; a link to external data connected to the gas-cooled three-dimensional integrated circuit; and a power source in communication with the gas-cooled three-dimensional integrated circuit, and optionally a clock signal linked to the gas-cooled three-dimensional integrated circuit.

In accordance with another aspect of the present disclosure, there is provided a system including a three-dimensional integrated circuit, including two or more stacks of one or more active layers, a gas-cooling layer separating the two or more stacks and a wireless interconnect between the two or more stacks enabling communication between the two or more stacks; a gas source in fluid communication with the gas-cooling layer; a link to external data connected to the three-dimensional integrated circuit; and a power source in communication with the three-dimensional integrated circuit, optionally a clock signal linked to the three-dimensional integrated circuit.

These and other aspects of the present disclosure will become apparent upon a review of the following detailed description and the claims appended thereto.

### BRIEF DESCRIPTION OF THE DRAWINGS

FIG. 1 shows a side view of a cross-section of a 3D IC in accordance with an embodiment of the present invention.

### DETAILED DESCRIPTION

An embodiment of the present disclosure relates to a three-dimensional integrated circuit, including two or more stacks of one or more active layers; a gas cooling layer separating the two or more stacks; wireless interconnects between the two or more stacks enabling communication of data between the two or more stacks and wired interconnects within the two or more stacks enabling communication within the two or more stacks and system incorporating the device.

In the present application “a three-dimensional integrated circuit” (3D IC) refers to an integrated circuit (IC) composed of multiple integrated active adjacent layers. An active layer refers to a semiconductor die with transistor based circuits and interconnects implementing analog or digital integrated circuits spanning dimensions, typically of from about 5 mm×5 mm to about 30 mm×30 mm. Each active layer can be about 4 microns to about 1 mm in thickness. Each active layer can be composed of multiple core blocks connected with an interconnection mechanism, such as a Network-on-Chip (NoC). The NoC spans cores within multiple active layers and is responsible for data communication between the cores.

The NoC is an interconnection network for multicore chips including 3D multicore ICs where data is routed between cores through pipelined links and switches.

The 3D IC package will be connected to a platform or substrate such as a printed circuit board (PCB) that will house the whole system or environment of the 3D IC. The interconnections between the 3D IC package and the substrate can be achieved using Ball Grid Array (BGA), C4 bumps, solder bumps or wire bonded.

The substrate can be a platform such as a PCB where the 3D IC along with other multiple chips or other 3D ICs could be mounted and interconnected using metal traces between them.

Stacks of one or more active layers refers to adjacent integrated dies, e.g., vertically stacked, which are active semiconductor layers implementing digital or analog circuits. Typically, there will one or more such layers stacked. The number of layers that can be suitably placed in a stack depends upon the collective power and heat dissipation of the layers and the cooling capability of the gas cooling layer between the stacks. The vertical heights of each active layer can vary greatly depending upon the manufacturing process and can range from about 4 microns to about 100 microns. The planar span of such layers can be from about 10 mm×10 mm to about 30 mm×30 mm. In other embodiments, different aspect ratios and different sizes on upper and lower ranges for the planar span of such layers can be employed.

The gas-cooling layer can have any suitable structure that enables sufficient gas flow through the layer. An embodiment of the gas-cooling layer includes a gas-cooling channel disposed between the stacks of active layers. The cooling layer can contain multiple gas-cooling channels. The channels may be in parallel thereby distributing the total gas flow rate through each of them. In another embodiment, the microchannels are replaced with a field of fins that act as pillars across the height of the channels. These fins may be of any suitable cross section to promote heat transfer. Considerations may be given to design the fin geometry and configuration to keep the pressure drop low. Some of the fins may be short, meaning they do not connect the top and bottom of the cooling channel walls. Any combination of microchannels, full fin or short fin structures of any geometry may be employed to dissipate heat from the gas cooling layer channel walls to the flowing gas. A suitable gaseous coolant, which includes air, helium, nitrogen, mixtures thereof and the like, flows through the channels and removes heat from the active layers. A gas-cooling channel can have a width of from about 100 microns to about the entire width of the cooling layer; a height normal to the substrate of from about 100 microns to about 10 mm, preferably, about 100 microns to about 3 mm, and more preferably about 100 microns to about 1 mm. The cooling layer can be fabricated as a separate layer and then embedded between the stacks of active layers. Alternatively, the cooling channels can be etched directly onto the surfaces of the active layers. The cooling channels may contain support structures to provide mechanical integration. The cooling channels may contain enhancement structures such as full-height fins, short fins, fins of any cross-section, swirl generators, dimples, roughness features and like. Other types of enhancement features may also be included. The purpose of the enhancement features is to increase the heat transfer rate. It should be balanced against the pressure drop penalty incurred in the gasflow.

Each active layer can be equipped with one or more wireless transmitters and receivers which are capable of communicating data directly between each active layer and within each active layer. This enables data communication between the active layers which are separated by the gas cooling layer as well. The wireless communication is also established between laterally distant wireless nodes as well. The wireless transceivers are shown to be more energy-efficiency compared to conventional wired data communication within a chip when the distance spanned is larger than a certain threshold. Depending upon the design of the transceiver and the technology node of implementation that energy-efficiency threshold distance can be as short as about 3 to 5 mm. Therefore, lateral communication between distant processor blocks through the wireless links will be more energy efficient compared to the conventional wired communication. Therefore, the NoC spanning the 3D IC will be augmented with wireless links which will be used to route data when the distance is preferably more than about 3 to 5 mm to enable energy efficient lateral communication between cores. However, wireless interconnects can be used for lengths of shorter distances. Also when the stacks are separated by a cooling layer the data communication happens only through wireless links when there are no TSV based wired links across the cooling layer. As an example, the wireless links can operate in the 60 GHz millimeter-wave bands. A suitable transceiver includes a power-efficient non-coherent On-Off-Keying (OOK) modulator/demodulator. Other higher order modulations can be used if preferred and if it provides a power-efficient circuit design. Suitable antennas include metal zig-zag antennas embedded in a layer of silica on a surface of the active layer about 2 to 5 microns thick. Other antenna shapes are also possible, such as patch antenna, linear antenna or ring antennas. The antennas are tuned to operate at frequency of the wireless links and provide the best power gains across the cooling layers and laterally to other antennas. The cooling layers can be from about 100 microns to about 1000 microns in height and therefore, the antennas need to be able to communicate vertically to other antennas which may be separated by a distance of from about 10 microns (in the case of adjacent active layers not separated by cooling layers) to thousands of microns (in case of active layers separated by one or more cooling layers) or more. It is desirable from the perspective of wireless communication across the cooling layers that the gas circulating in the cooling channels is air as air has lower dielectric constant compared to liquid coolants.

Between stacks of active layers where the active layers are not separated by a cooling layer the vertical NoC links are realized with Through-Silicon-Via (TSV). Lateral NoC links within each active layer is realized with traditional global wires in a NoC topology such as mesh or tree. However, the data routing typically uses the wireless links when the physical distance between the pair of cores is longer than the energy-efficiency threshold distance.

The wireless links can be realized in frequency bands spanning from about 10 GHz to more than about 1 THz depending upon the implementation technology. Typically the sustainable data rates are a fraction of the carrier frequency. As an example, the wireless links can sustain about 16 to about 20 Gbps data rates in the approximately 60 GHz band and this rate can increase by utilizing other bands beyond 500 GHz. Such wireless links can communicate at up to about 10 cm range of communication.

Realizing the wireless data links across the cooling layers can eliminate 10,000 or even more vertical data TSVs. This makes place and route of power and clock TSVs across the cooling layers through the cooling-channel walls easier, if required. Data communication across the cooling layers using the wireless links frees up room for routing clock and power TSVs through the microchannel walls.

The gas-cooling channel with air cooling is a complementary technology for the wireless interconnects across the cooling layer as the air has the lowest dielectric constant thereby reducing the path loss in the communication channel. Similarly, the wireless interconnects is a complementary technology for gas cooling channel technology as it enables data transmission over longer distances dictated by the gas cooling channel height as compared to the conventional channel heights employed in liquid cooling technology.

The integrated circuit can achieve a heat dissipation of from about 1 W/cm² to 250 W/cm² from each interface between the cooling layer and active layer.

The integrated circuit includes gas cooling having a pressure drop of from about 0.1 kPa to about 100 kPa. A more preferred range includes a pressure drop from about 0.5 kPa to about 20 kPa. The floor plan of the 3D IC can be modified to shorten the length of the gas cooling channel to reduce the pressure drop.

The use of air cooling in microchannels was typically considered to result in a greater pressure drop with poor heat transfer, and thus less desirable when compared to liquid cooling. Accordingly, in the past the 3D IC architecture was based on liquid cooling with short TSVs. This configuration results in significant design constrains. Using wireless communication removes the TSV constraint and employing air cooling provides a highly desirable cooling option. Air is preferred over liquid as a coolant since it has been well established for electronics cooling application, it has low dielectric constant and there are no leakage concerns. Air cooling can also be easily integrated with the existing cooling infrastructure from HVAC systems where they exist. In the case of other applications without an HVAC system, direct circulation of surrounding air provides a very desirable option.

The present solution offers a low cost alternative for designing high performing 3D IC architecture with acceptable thermal characteristics. This invention combines innovations from three different fields, computer architecture, IC design and cooling. The invention allows dissipation of high heat fluxes at high heat transfer coefficients employing air as the working fluid. It allows the low cost alternative of air cooling in dissipating heat from 3D IC architecture. The low cost arises because air is available freely and an air cooled system cost is lower than the single-phase liquid cooled or two-phase cooled systems.

The 3D IC is housed in a system which can be mounted and integrated on a board, such as a PCB. The 3D IC can be a part of a larger system such as an electronic system, server, datacenter or smart device such as a smart phone where performance and/or power consumption are important constraints. In such an environment liquid cooling may not be very desirable due to possibility of leaking. In an embodiment, power supply to the various layers of the 3D IC and other non-data signals such as the clock can be routed using TSVs across the cooling layers. Eliminating data TSVs across the cooling layer makes routing power and clock TSVs across the cooling layer or the microchannel walls relatively easy from the perspective of place and route of TSVs. However, with design of transmitters and receivers at other frequencies clock signals at different frequencies can be delivered wirelessly to the different active layers across the cooling layers. Also, with wireless power transfer using antennas power signals can also be transferred across the cooling layer to active layers. Therefore, embodiments can utilize wireless power and clock transfer in addition to wireless data transfer.

In an embodiment, a system includes a gas-cooled three-dimensional integrated circuit having wireless interconnects in accordance with the present disclosure; a gas source in fluid communication with the gas-cooling layer of the three-dimensional integrated circuit; a link to external data connected to the three-dimensional integrated circuit; a power source in communication with the three-dimensional integrated circuit; and optionally a clock signal linked to the three-dimensional integrated circuit. In systems such as a High Performance Computer or Datacenter it is possible to integrate the already existing air cooling system using HVAC to provide the chilled air into the gas cooling channels formed by microchannels or finned passages in the gas cooling layers in the 3D IC. This eliminates additional infrastructure that is required to enable liquid cooling. Alternatively, the supply or return gas from the gas cooling layer may be cooled in a heat exchanger that interfaces with the available gas cooling infrastructure. The 3D IC within the overall system is connected to an external data link through metallic solder bumps on the substrate or photonic or wireless links or any other technology suitable for data transfer. The 3D IC is connected to power supply through wired or wireless connections. The 3D IC can also receive clock signals as well from external clock sources through wired or wireless links.

With the progress in technology the wireless links can be realized with non-CMOS technology such as nano-antennas based on graphene, silicon and carbon nanotube based antennas. These will be able to reduce the power consumption in wireless data transfer and increase the speed in data transfer by orders of magnitude even compared to mm-wave CMOS wireless links. Even CMOS wireless transceivers and antennas tuned to other frequencies spanning up to about 500 GHz can be used to provide multiple frequency bands to enhance the data transfer speeds in the 3D IC.

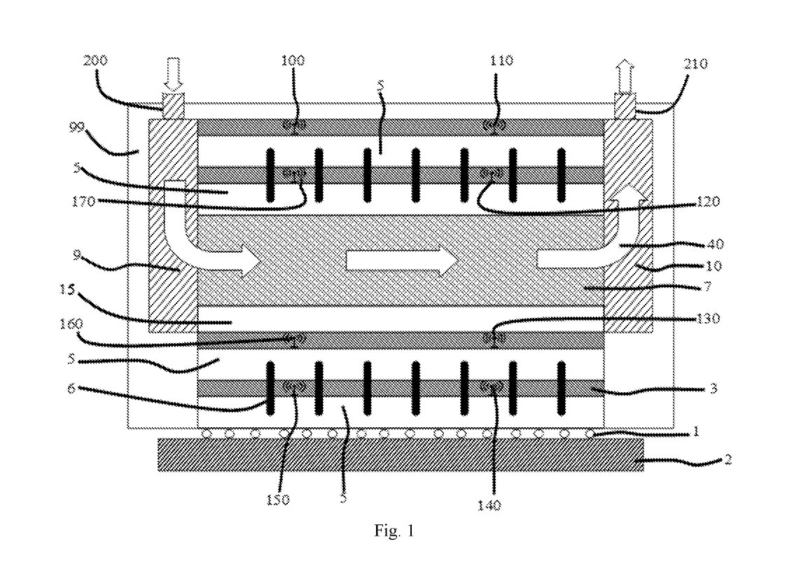

FIG. 1 represents a side view of a cross-section of a 3D IC in accordance with an embodiment of the present invention. The 3D IC contains two stacks of active layers 5 with two active layers 5 in each stack. In other embodiments, a stack may include one or more active layers. In other embodiments, a 3D IC may include one or more stacks, wherein each stack is separated by a gas cooling layer. Further, in another embodiment, a gas cooling layer may be placed at the end face of a stack or the 3D IC. The entire 3D IC is mounted on a PCB substrate 2 and connected with bumps 1. Active layers 5 within each stack are connected by TSVs 6. Wireless data communication can be achieved between wireless nodes 100, 110, 170, 120, 160, 130, 150 and 140, as desired. The wireless communication between laterally separated wireless nodes, such as 100 and 110 or 100 and 120, saves energy compared to wired transfer between these locations. The wireless antennas are embedded in a layer of silicon dioxide 3 which may be a part of the active layer or may be a separate layer adjacent the active layer. The TSV 6 based vertical data links are shown between active layers 5 inside a single stack of active layers 5. The floor of the gas-cooling channel 15 and the recessed back wall 7 of the gas-cooling channel are shown in the side view perspective of the 3D IC in FIG. 1 as the cross-section is taken parallel along the center of the channel. Together the floor of the gas-cooling channel 15 and the recessed back wall 7 as shown form a portion of the gas-cooling layer. In another embodiment, the gas cooling layer may be composed of a floor and ceiling in the flow passage adjacent the channel wall. In another embodiment, the gas cooling layer may incorporate different flow channel configurations that may include fins, enhancement structures, multiple parallel channels, and the like. The arrows 40 represent the flow of gas coolant from the inlet 200 to the outlet 210. The inlet manifold 9 and exit manifold 10 respectively guide the gas coolant into and out of the cooling layer. In another embodiment, inlet manifold 9 and exit manifold 10 can respectively guide the gas coolant into and out of multiple cooling layers as well as in multiple gas-cooling channels in the same cooling layer. A casing 99 encloses the entire 3D IC.

Although various embodiments have been depicted and described in detail herein, it will be apparent to those skilled in the relevant art that various modifications, additions, substitutions, and the like can be made without departing from the spirit of the disclosure and these are therefore considered to be within the scope of the disclosure as defined in the claims which follow.

What is claimed:

1. A three-dimensional integrated circuit, comprising:
two or more stacks of one or more active layers;
a gas-cooling layer separating the two or more stacks and
a wireless interconnect between the two or more stacks enabling communication between the two or more stacks.

2. The device of claim 1, further comprising wireless interconnects between the one or more active layers enabling communication within the one or more active layers.

3. The device of claim 1, further comprising data TSV's between two stacks of the two or more stacks.

4. The device of claim 1, further comprising data TSV's between two active layers within a stack.

5. The device of claim 1, wherein the gas-cooling layer comprises a channel having a width of from about 0.1 mm to about the width of the gas-cooling layer.

6. The device of claim 1, wherein the gas-cooling layer comprises a channel having a height of from about 0.1 mm to about 10 mm.

7. The device of claim 1, wherein the gas-cooling layer comprises single or multiple flow passages that include one or more enhancement features.

8. The device of claim 1, wherein the integrated circuit comprises a heat dissipation of from about 1 W/cm² to about 250 W/cm² from each interface between the cooling layer and active layer.

9. The device of claim 1, wherein the gas cooling layer comprises a pressure drop of from about 0.1 kPa to about 100 kPa.

10. The device of claim 1, wherein the communication comprises at least one of data, power, and clock timing.

11. A system comprising:
a gas-cooled three-dimensional integrated circuit comprising internal wireless data interconnects;
a gas source in fluid communication with the gas-cooled three-dimensional integrated circuit;
a link to external data connected to the gas-cooled three-dimensional integrated circuit; and
a power source in communication with the gas-cooled three-dimensional integrated circuit, and optionally a clock signal linked to the gas-cooled three-dimensional integrated circuit.

12. The system of claim 11, wherein the gas-cooled three-dimensional integrated circuit, comprises:
two or more stacks of one or more active layers;
a gas-cooling layer separating the two or more stacks and
a wireless interconnect between the two or more stacks enabling communication between the two or more stacks

13. The system of claim 12, further comprising wireless interconnects between the one or more active layers enabling communication within the one or more active layers.

14. The system of claim 12, further comprising data TSV's between two stacks of the two or more stacks.

15. The system of claim 12, further comprising data TSV's between two active layers within a stack.

16. The system of claim 12, wherein the gas-cooling layer comprises a channel having a width of from about 0.1 mm to about the width of the gas-cooling layer.

17. The system of claim 12, wherein the gas-cooling layer comprises a channel having a height of from about 0.1 mm to about 10 mm.

18. The system of claim 12, wherein the gas-cooling layer comprises single or multiple flow passages that include one or more enhancement features.

19. The system of claim 12, wherein the integrated circuit comprises a heat dissipation of from about 1 W/cm² to about 250 W/cm² from each interface between the cooling layer and active layer.

20. The system of claim 12, wherein the gas cooling layer comprises a pressure drop of from about 0.1 kPa to about 100 kPa.
